(19) United States
(12) Patent Application Publication
(10) Pub. No.: US 2006/0081877 A1
(43) Pub. Date: Apr. 20, 2006

(54) Semiconductor epitaxial wafer and field effect rtansistor

(75) Inventors: Yoshiharu Kohji, Hitachi (JP); Takeshi Tanaka, Tokaimura (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Hitachi Cable, Ltd., Tokyo (JP)

(21) Appl. No.: 11/097,256

(22) Filed: Apr. 4, 2005

(30) Foreign Application Priority Data
Oct. 14, 2004 (JP) 2004-299821

(51) Int. Cl. H01L 29/221

(52) U.S. Cl. 257/194

(57) ABSTRACT

A semiconductor epitaxial wafer has, on a sapphire substrate, an AlN buffer layer formed of undoped AlN, a GaN buffer layer formed of 2 μm-thick undoped GaN, and measurement electrodes formed thereon.

The present application is based on Japanese patent application No. 2004-299821, the entire contents of which are incorporated herein by reference.

### BACKGROUND OF THE INVENTION

1. Field of the Invention

The present invention relates to a semiconductor epitaxial wafer, and particularly, to a semiconductor epitaxial wafer suitably used in fabricating field effect transistors (FETs) including high electron mobility transistors (HEMTs), etc., and an FET derived therefrom.

2. Description of the Related Art

Field effect transistors including high electron mobility transistors (HEMTs) control current flowing between source and drain electrodes by spreading of a depletion layer from a gate electrode.

In fabricating a semiconductor epitaxial wafer on which an epitaxial layer comprising gallium nitride (GaN) is grown, however, no sufficient technique for cleaning an interface between an epitaxial layer and a substrate has been established, and no high-purity ammonia (NH₃) gas that is one of raw material gases has been obtained, so that conductive impurities tend to be mixed into the epitaxial layer.

And as a result, despite the fact that a buffer layer requires higher insulation compared to other layers, as a result of conductive impurities being mixed into the buffer layer, there is the problem that the buffer layer exhibits high conductivity in a degree close to the conductivity of a channel layer. This tendency is remarkable particularly in a portion close to the substrate of the buffer layer.

Such a problem becomes the cause for the depletion layer being difficult to spread from the gate electrode.

Also, as a result of conductive impurities being mixed into the buffer layer, there is formed a portion (a conductive layer) having high conductivity in a portion close to the substrate of the buffer layer, and a current flows therethrough, so that an electronic device having good characteristics (pinch-off characteristics close to an ideal shown in FIG. 3) is difficult to be obtained

For example, Japanese patent application laid-open No. 2001-102564 and No. 2002-50758 describe electronic devices (HEMT, FET) in which a GaN buffer layer is formed on a sapphire substrate or a silicon carbide (SiC) substrate, which is considered to provide no sufficient characteristics because of the above reason.

### SUMMARY OF THE INVENTION

Accordingly, it is an object of the present invention to provide a semiconductor epitaxial wafer suitably used in fabricating field effect transistors (FETs, HEMTs), which realizes high characteristics by preventing the above defects which degrade characteristics, and more specifically, by preventing the formation of a portion (a conductive layer) having high conductivity in the buffer layer due to conductive impurities mixed into the epitaxial layer.

To achieve the above object, the present invention provides a semiconductor epitaxial wafer having a substrate, on which is formed a buffer layer comprising sequentially an aluminum nitride buffer layer (AlN buffer layer) and a gallium nitride buffer layer (GaN buffer layer).

In the semiconductor epitaxial wafer, it is preferred that the thickness of the AlN buffer layer is 0.2 μm or more.

In the semiconductor epitaxial wafer, it is preferred that the thickness of the AlN buffer layer is 0.2 μm or more; the thickness of the GaN buffer layer is 0.5 μm or more; and the total thickness of the buffer layer is 0.7 μm or more.

The present invention also provides a semiconductor epitaxial wafer having a substrate, on which is formed a buffer layer comprising sequentially an In_{X}Ga_{1-X}N buffer layer (0≦X≦1), an AlN buffer layer and a GaN buffer layer.

In the semiconductor epitaxial wafer, it is preferred that the thickness of the AlN buffer layer is 0.2 μm or more.

In the semiconductor epitaxial wafer, it is preferred that the thickness of the In_{X}Ga_{1-X}N buffer layer is 0.01 μm or more; the thickness of the AlN buffer layer is 0.2 μm or more; the thickness of the GaN buffer layer is 0.5 μm or more; and the total thickness of the buffer layer is 0.71 μm or more.

In the semiconductor epitaxial wafer, it is preferred that the substrate comprises a sapphire substrate or a SiC substrate.

In the semiconductor epitaxial wafer, it is preferred that the dislocation density of the buffer layer is 1×10⁸ cm⁻² or more.

The present invention also provides a field effect transistor comprising a semiconductor epitaxial wafer comprising a substrate, on which are sequentially formed: a buffer layer comprising sequentially an AlN buffer layer and a GaN buffer layer; a channel layer comprising undoped GaN; an electron supply layer comprising n-type doped AlGaN; a cap layer formed on the electron supply layer; a gate electrode formed on the electron supply layer; a source electrode and a drain electrode formed on the cap layer.

In accordance with the invention, it can provide a semiconductor epitaxial wafer suitably used in fabricating field effect transistors (FETs, HEMTs), which realizes high characteristics by preventing the formation of a portion (a conductive layer) having high conductivity in the buffer layer due to conductive impurities mixed into the epitaxial layer.

### BRIEF DESCRIPTION OF THE DRAWINGS

The preferred embodiments according to the invention will be explained below referring to the drawings, wherein:

FIG. 1 is a cross-sectional view illustrating a characteristic-measuring device fabricated using a conventional semiconductor epitaxial wafer;

FIG. 2 is a cross-sectional view illustrating a high electron mobility transistor (HEMT) fabricated using a conventional semiconductor epitaxial wafer;

FIG. 3 is a diagram showing pinch-off characteristics of a high electron mobility transistor (HEMT) fabricated using a conventional semiconductor epitaxial wafer, and ideal pinch-off characteristics in the high electron mobility transistor (HEMT);

FIG. 4 is a cross-sectional view illustrating a characteristic-measuring device fabricated using a semiconductor epitaxial wafer in a first preferred embodiment of the present invention;

FIG. 5 is a cross-sectional view illustrating a high electron mobility transistor (HEMT) fabricated using the semiconductor epitaxial wafer in the first embodiment of the present invention;

FIG. 6 is a cross-sectional view illustrating a characteristic-measuring device fabricated using a semiconductor epitaxial wafer in a second preferred embodiment of the present invention;

FIG. 7 is a cross-sectional view illustrating a high electron mobility transistor (HEMT) fabricated using the semiconductor epitaxial wafer in the second embodiment of the present invention;

FIG. 8 is a diagram showing the relationships between AlN buffer layer thickness, current and dislocation density in the semiconductor epitaxial wafer of the present invention; and

FIG. 9 is a diagram showing the relationship between dislocation density and current in the semiconductor epitaxial wafer of the present invention.

### DETAILED DESCRIPTION OF THE PREFERRED EMBODIMENTS

Embodiments of the present invention are explained in detail below based on the accompanying drawings.

### First Embodiment

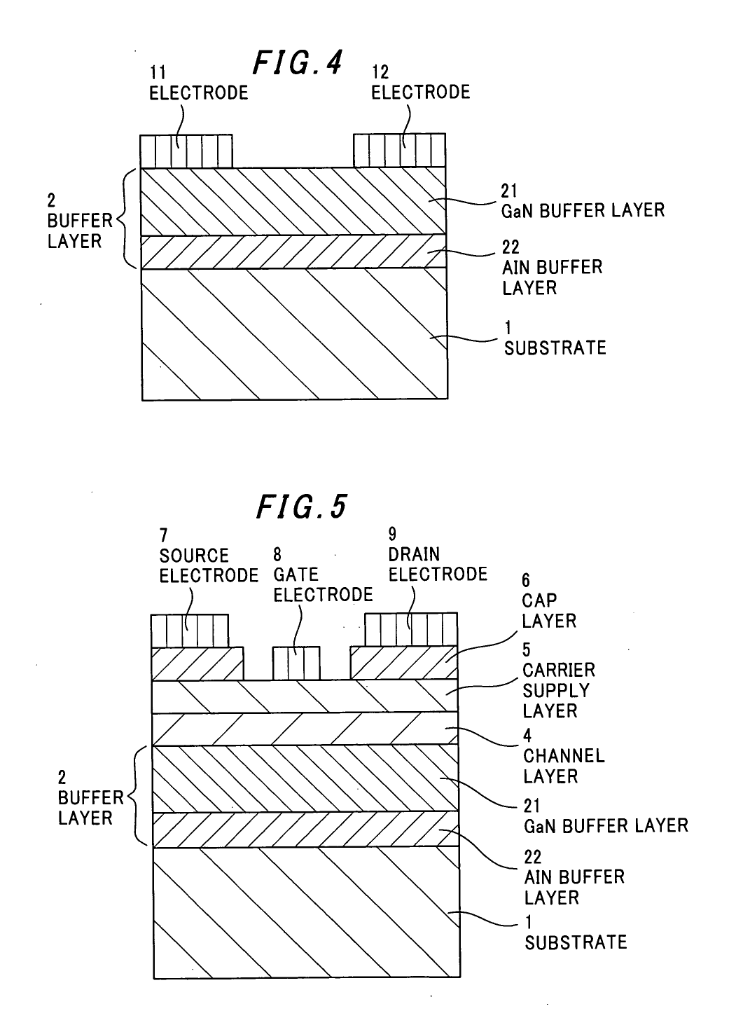

FIG. 4 is a cross-sectional view illustrating a semiconductor epitaxial wafer in the first preferred embodiment of the present invention.

Concretely, the structure illustrated in FIG. 4 is a characteristic-measuring device fabricated by using the semiconductor epitaxial wafer in the first embodiment of the present invention, to measure characteristics (conductivity, dislocation density) of a buffer layer 2 comprising an AlN buffer layer 22 and a GaN buffer layer 21. It comprises, on a sapphire substrate 1, the AlN buffer layer 22 of undoped AlN, the GaN buffer layer 21 of 2 μm-thick undoped GaN, and measurement electrodes 11 and 12 formed thereon. And, in the above characteristic-measuring device, three characteristic-measuring devices with AlN buffer layer 22 thicknesses of 0.1, 0.2 and 0.3 μm are fabricated.

Epitaxial growth of the semiconductor epitaxial wafer used in this characteristic-measuring device used metal organic vapor epitaxy (MOVPE). Here, gallium raw-material used trimethyl gallium (TMG); aluminum raw-material used trimethyl aluminum (TMA); nitrogen raw-material used ammonia gas; and carrier gas used hydrogen.

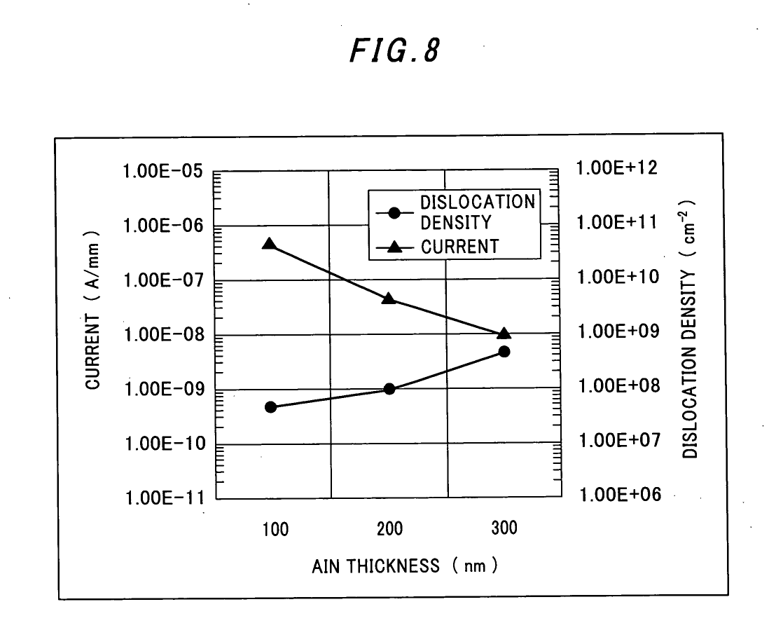

FIG. 8 is a diagram showing the relationships in this case between AlN thickness (AlN buffer layer 22 thickness, [nm]), conductivity (current, [A/mm]) and dislocation density ([cm⁻²]). Further, conductivity assessment used applying a voltage of 10 V to the semiconductor epitaxial wafer illustrated in FIG. 4, measuring current flowing therein and comparing it.

As a result, when a buffer layer 2 comprising an AlN buffer layer 22 and a GaN buffer layer 21 was formed, especially in the case of a 0.2 μm or more thick AlN buffer layer 22, a very small current (low conductivity) could be obtained. Specifically, in 0.1 μm thick AlN, the current obtained was 5×10⁻⁷ A/mm; in 0.2 μm thick AlN, the current obtained was 5×10⁻⁸ A/mm, and in 0.3 μm thick AlN, the current obtained was 1×10⁻⁸ A/mm.

Also, the dislocation density of AlN buffer layer 22 was then 5×10⁷ cm⁻² for 0.1 μm thick AlN; 1×10⁸ cm⁻² for 0.2 μm thick AlN; and 5×10⁸ cm⁻² for 0.3 μm thick AlN.

Further, in practice, when FET is fabricated using the first embodiment of the semiconductor epitaxial wafer of the present invention, AlN is preferably 0.2 μm or more thick. This is because, in 0.2 μm or more thick AlN, the dislocation density decreases below 1×10⁹ cm⁻² which is considered to cause no practical problems.

FIG. 5 is a cross-sectional view illustrating a HEMT fabricated using the first embodiment of the semiconductor epitaxial wafer in the second embodiment of the present invention.

The HEMT illustrated in FIG. 5 comprises a sapphire substrate 1 on which are sequentially formed an AlN buffer layer 22 of 0.3 μm-thick undoped AlN, a GaN buffer layer 21 of 2 μm-thick undoped GaN, a channel layer 4 of 0.1 μm-thick undoped GaN, and a carrier supply layer 5 of 0.025 μm-thick n-type AlGaN, and a 0.002 μm-thick cap layer 6 formed thereon. And, formed on the carrier supply layer 5 is a gate electrode 8, while formed on the cap layer 6 are a source electrode 7 and a drain electrode 9.

Epitaxial growth of the epitaxial wafer of this HEMT used metal organic vapor epitaxy (MOVPE). Also, gallium raw-material used trimethyl gallium (TMG); aluminum raw-material used trimethyl aluminum (TMA); nitrogen raw-material used ammonia gas; carrier gas used hydrogen; and n-type dopant used monosilane. Epitaxial growth used a face-up heater depressurization furnace (not shown), within which the pressure was set to 13,332 Pa (100 Torr).

It was verified, from results of measuring characteristics of the HEMT thus fabricated, that a decrease in the buffer layer conductivity allowed having good pinch-off characteristics (pinch-off voltage: −4.1V).

### Second Embodiment

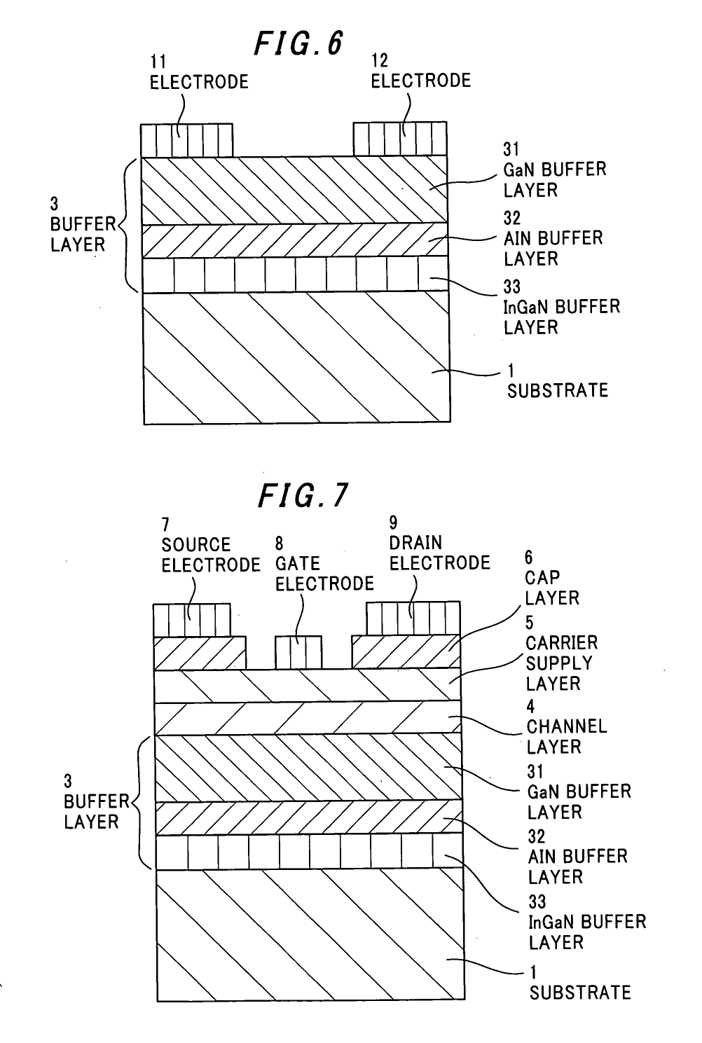

FIG. 6 is a cross-sectional view illustrating a semiconductor epitaxial wafer in the second embodiment of the present invention.

Concretely, the structure illustrated in FIG. 6 is a characteristic-measuring device fabricated by using a second embodiment of a semiconductor epitaxial wafer of the present invention, to measure characteristics (conductivity, dislocation density) of a buffer layer 3 comprising an InGaN buffer layer 33, an AlN buffer layer 32 and a GaN buffer layer 31. It comprises, on a sapphire substrate 1, the InGaN buffer layer 33 of 0.01 μm-thick InGaN with an In composition ratio of 0.05, the AlN buffer layer 32 of AlN, the GaN buffer layer 31 of 2 μm-thick undoped GaN, and measurement electrodes 11 and 12 formed thereon. And, in the above semiconductor epitaxial wafer structure, three semiconductor epitaxial wafers with AlN buffer layer 32 thicknesses of 0.1, 0.2 and 0.3 μm were fabricated.

Epitaxial growth of the semiconductor epitaxial wafers used in this characteristic-measuring device used metal organic vapor epitaxy (MOVPE), in the same manner as the first embodiment. Also, in the same manner as the first embodiment, gallium raw-material used trimethyl gallium (TMG); aluminum raw-material used trimethyl aluminum (TMA); nitrogen raw-material used ammonia gas; and indium raw-material used trimethyl indium (TMI).

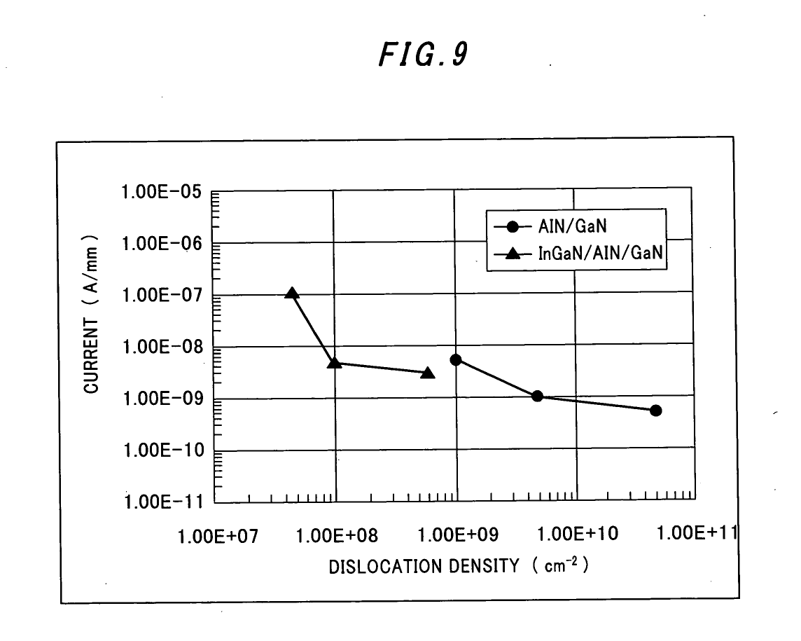

In this manner, by forming a buffer layer 3 comprising an InGaN buffer layer 33, an AlN buffer layer 32 and a GaN buffer layer 31, a very small current (low conductivity) could be obtained with the same degree as The first embodiment 1. Furthermore, as shown in FIG. 9, compared to the first embodiment where a buffer layer 2 comprising an AlN buffer layer 22 and a GaN buffer layer 21 was formed, a lower dislocation density could be obtained.

FIG. 7 is a cross-sectional view illustrating a HEMT fabricated using the second embodiment of the semiconductor epitaxial wafer in the second embodiment of the present invention.

The HEMT illustrated in FIG. 7 comprises a sapphire substrate 1 on which are sequentially formed a InGaN buffer layer 33 of 0.01 μm-thick undoped InGaN with an In composition ratio of 0.05, a AlN buffer layer 32 of 0.3 μm-thick undoped AlN, a GaN buffer layer 31 of 2 μm-thick undoped GaN, a channel layer 4 of 0.1 μm-thick undoped GaN, and a carrier supply layer 5 of 0.025 μm-thick n-type AlGaN, and a 0.002 μm-thick cap layer 6 formed thereon. And, formed on the carrier supply layer 5 is a gate electrode 8, while formed on the cap layer 6 are a source electrode 7 and a drain electrode 9.

Epitaxial growth of this HEMT used metal organic vapor epitaxy (MOVPE), in the same manner as the first embodiment. Also, in the same manner as first embodiment, gallium raw-material used trimethyl gallium (TMG); aluminum raw-material used trimethyl aluminum (TMA); nitrogen raw-material used ammonia gas; carrier gas used hydrogen; and n-type dopant used monosilane. Epitaxial growth used a face-up heater depressurization furnace (not shown), within which the pressure was set to 13,332 Pa (100 Torr).

It was verified, from results of measuring characteristics of the HEMT thus fabricated, that a decrease in the buffer layer conductivity allowed having good pinch-off characteristics (pinch-off voltage: −4.0V).

### Comparative Example 1

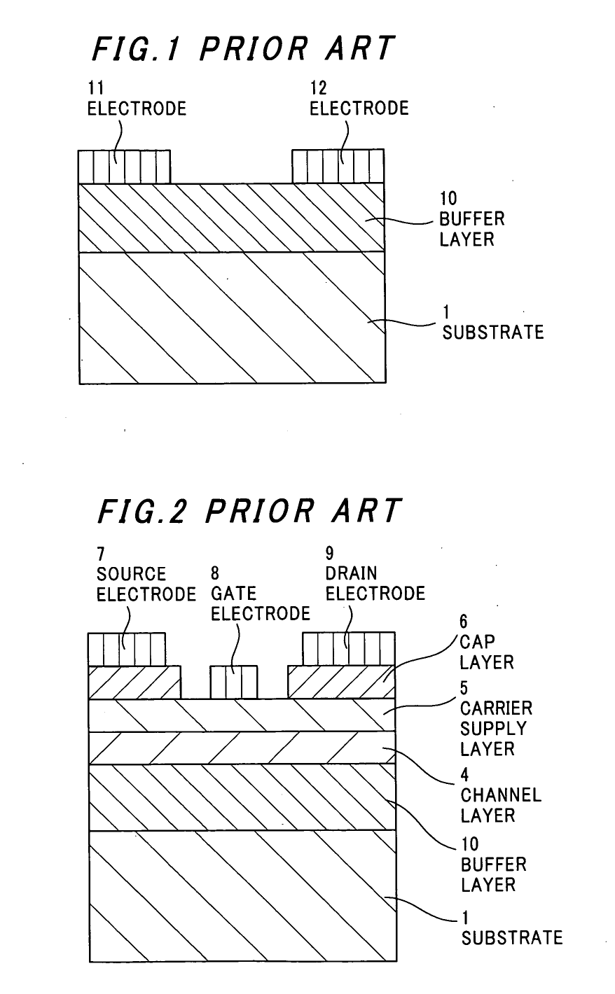

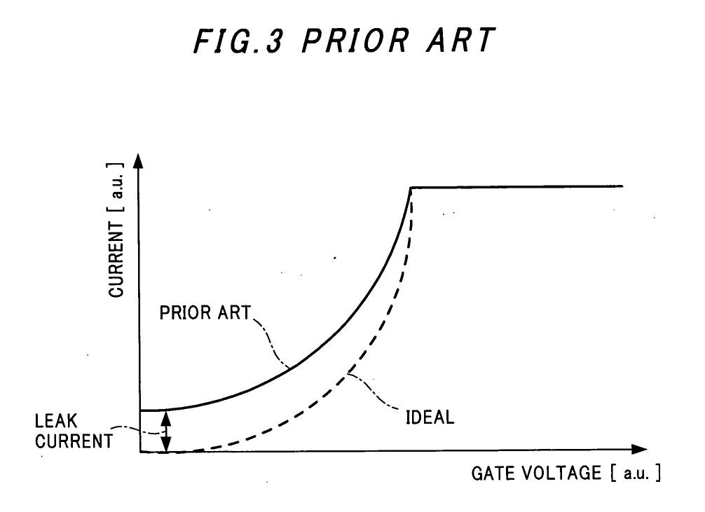

FIG. 1 is a cross-sectional view illustrating a semiconductor epitaxial wafer, as a Comparative Example to semiconductor epitaxial wafers of the above first and second embodiments.

Concretely, the structure illustrated in FIG. 1 is a characteristic-measuring device fabricated by using a semiconductor epitaxial wafer as a Comparative Example to semiconductor epitaxial wafers of the above first and second embodiments, to measure characteristics (conductivity, dislocation density) of a GaN buffer layer 10. It comprises, on a sapphire substrate 1, the 2 μm-thick GaN buffer layer 10, and measurement electrodes 11 and 12 formed thereon. Further, epitaxial growth of this semiconductor epitaxial wafer and raw materials used therein are the same as those used in growing the GaN buffer layer of the above first and second embodiments.

As a result, the current obtained was 1×10⁻¹ A/mm, which was a large current (high conductivity), compared to that of the above first and second embodiments.

FIG. 2 is a cross-sectional view illustrating a HEMT fabricated using a semiconductor epitaxial wafer as a Comparative Example to semiconductor epitaxial wafers of the above first and second embodiments.

The HEMT illustrated in FIG. 2 comprises a sapphire substrate 1 on which are sequentially formed a buffer layer 10 of 2 μm-thick undoped GaN, a channel layer 4 of 0.1 μm-thick undoped InGaN, and a carrier supply layer 5 of 0.025 μm-thick n-type AlGaN, and a 0.002 μm-thick cap layer 6 formed thereon. And, formed on the carrier supply layer 5 is a gate electrode 8, while formed on the cap layer 6 are a source electrode 7 and a drain electrode 9.

Epitaxial growth of this HEMT used metal organic vapor epitaxy (MOVPE), in the same manner as the first and second embodiments. Also, in the same manner as the first embodiment, gallium raw-material used trimethyl gallium (TMG); aluminum raw-material used trimethyl aluminum (TMA); nitrogen raw-material used ammonia gas; carrier gas used hydrogen; and n-type dopant used monosilane. Epitaxial growth used a face-up heater depressurization furnace (not shown), within which the pressure was set to 13,332 Pa (100 Torr).

As a result of measuring characteristics of the HEMT thus fabricated, no pinch-off could be measured. In other words, it was verified that, because of no decrease in the buffer layer conductivity as in the first and second embodiments, it had no good pinch-off characteristics as in the first and second embodiments.

### Other embodiments, Modified Embodiments

While a sapphire substrate was used as the substrate in the above first and second embodiments, a silicon carbide (SiC) may be used as the substrate. Even in that case, similar effects to those of the case where a sapphire substrate was used as the substrate 1 can be obtained.

In the above second embodiment, while an InGaN buffer layer with an In composition ratio of 0.05 was used, the invention is not particularly limited thereto, and includes an InGaN buffer layer with an In composition ratio from 0 to 1. Namely, it includes the cases of an In composition ratio of 0 (GaN), and an In composition ratio of 1 (InN).

Further, in the case of a sapphire substrate used as the substrate, the most preferable In composition ratio in the InGaN buffer layer is 0.05. In the case of a SiC substrate used as the substrate, the most preferable In composition ratio in the InGaN buffer layer is 0.01. This is because, in the case of an In composition ratio of 0.05 in the InGaN buffer layer, the highest effect was the effect as the buffer layer between the sapphire substrate and the AlN buffer layer, while, in the case of an In composition ratio of 0.01 in the InGaN buffer layer, the highest effect was the effect as the buffer layer between the SiC substrate and the AlN buffer layer.

While the thickness of the GaN buffer layer was 2 μm in the above first embodiment, and the thicknesses of the GaN and InGaN buffer layers were 2 μm and 0.01 μm respectively in the above second embodiment, the invention is not particularly limited thereto. From the point of view of the effect as the buffer layer, it is preferred that the thicknesses of the GaN and InGaN buffer layers are 0.5 μm or more and 0.01 μm or more respectively.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor epitaxial wafer, comprising:
a substrate, on which is formed a buffer layer comprising sequentially an AlN buffer layer and a GaN buffer layer.

2. A semiconductor epitaxial wafer, comprising:
a substrate, on which is formed a buffer layer comprising sequentially an AlN buffer layer and a GaN buffer layer, wherein:
the thickness of the AlN buffer layer is 0.2 μm or more.

3. A semiconductor epitaxial wafer, comprising:
a substrate, on which is formed a buffer layer comprising sequentially an AlN buffer layer and a GaN buffer layer, wherein:
the thickness of the AlN buffer layer is 0.2 μm or more;
the thickness of the GaN buffer layer is 0.5 μm or more; and
the total thickness of the buffer layer is 0.7 μm or more.

4. A semiconductor epitaxial wafer, comprising:
a substrate, on which is formed a buffer layer comprising sequentially an In_{X}Ga_{1-X}N buffer layer (0≦X≦1), an AlN buffer layer and a GaN buffer layer.

5. A semiconductor epitaxial wafer, comprising:
a substrate, on which is formed a buffer layer comprising sequentially an In_{X}Ga_{1-X}N buffer layer (0≦X≦1), an AlN buffer layer and a GaN buffer layer, wherein:
the thickness of the AlN buffer layer is 0.2 μm or more.

6. A semiconductor epitaxial wafer, comprising:
a substrate, on which is formed a buffer layer comprising sequentially an In_{X}Ga_{1-X}N buffer layer (0≦X≦1), an AlN buffer layer and a GaN buffer layer, wherein:
the thickness of the In_{X}Ga_{1-X}N buffer layer is 0.01 μm or more;
the thickness of the AlN buffer layer is 0.2 μm or more;
the thickness of the GaN buffer layer is 0.5 μm or more; and
the total thickness of the buffer layer is 0.71 μm or more.

7. A semiconductor epitaxial wafer, according to claim 1, wherein:
the substrate comprises a sapphire substrate or a SiC substrate.

8. A semiconductor epitaxial wafer, according to claim 1, wherein:
the dislocation density of the buffer layer is 1×10⁸ cm⁻² or more.

9. A field effect transistor, comprising:
a semiconductor epitaxial wafer comprising a substrate, on which are sequentially formed a buffer layer comprising sequentially an AlN buffer layer and a GaN buffer layer;
a channel layer;
an electron supply layer;
a gate electrode;
a source electrode; and
a drain electrode the channel layer, the electron supply layer, the gat electrode and the source electrode being formed on the semiconductor epitaxial wafer.
